(19) United States
(12) Patent Application Publication
(10) Pub. No.: US 2007/0171741 A1
(43) Pub. Date: Jul. 26, 2007

(54) METHOD OF CURING ANALOG DEVICE FAIL THROUGH FAST TRANSISTOR

(76) Inventors: Young Seong Lee, Gyeonggi-do (KR); Kye Nam Lee, Gyeonggi-do (KR)

Correspondence Address: SHERR & NOURSE, PLLC, 620 HERNDON PARKWAY, SUITE 200, HERNDON, VA, 20170, US

(21) Appl. No.: 11/617,129

(22) Filed: Dec. 28, 2006

(30) Foreign Application Priority Data
Dec. 30, 2005 (KR) 10-2005-0134787

(51) Int. Cl. G11C 29/00

(52) U.S. Cl. 365/201

(57) ABSTRACT

Disclosed is a method of curing a failure of an analog device, wherein the operational range of a transistor is optimized, thereby curing a failure in the analog device and enhancing a yield. In the method, the target of the 1.5V high transistor is modified to a fast condition, thereby eliminating the ring type failure phenomenon caused by Fₘₐₓ. To this end, the manufacturing margin of a threshold voltage is set as 100 mV, the control specification of GC CD (Critical dimension) is set as ±0.013 μm, and the thickness specification of a gate oxide is set as 23±1 Å.

The present application claims priority under 35 U.S.C. 119 and 35 U.S.C. 365 to Korean Patent Application No. 10-2005-0134787 (filed on Dec. 30, 2005), which is hereby incorporated by reference in its entirety.

### BACKGROUND

As semiconductor technologies have recently made great advances in the multimedia field, semiconductors have handled not only information access and calculations but also visual and audio applications.

This type of semiconductor requires several IPs to perform these multiple functions. In order to accommodate the various IPs, the operational range of the component transistors must be optimized. However, as IP characteristics become more complicated, the range of available IPs becomes more limited.

In analog devices where high-frequency inputs and outputs are required, increasing transistor speeds must be attained without increasing leakage currents. Therefore, the functional area of transistors must be optimally designed to satisfy these two important conditions.

### SUMMARY

Embodiments relate to a method of curing a failure in an analog device, wherein the operational range of a transistor is optimized to increase the speed of the transistor and to prevent current leakage, so that the production yields can be enhanced.

Embodiments relate to a method of curing a failure in an analog device, wherein the margin of a threshold voltage is set to 100 mV, the control range of a gate CD (Critical dimension) is set as ±0.013 μm, and the thickness of gate oxide is set as 23±1 Å, thereby eliminating a ring type failure due to Fmx (Frequency MAX). Here, a skew lot, in which the threshold voltage window of a 1.5V standard is changed, may be used to evaluate the margin of the threshold voltage.

### BRIEF DESCRIPTION OF DRAWINGS

FIG. 1 is a wafer map showing a ring type failure of a center lot;

FIG. 2 is a graph showing an SRN trend of a 1.5V transistor;

FIG. 3 is a graph showing a change in yield of an nMOS 1.5V standard transistor;

FIG. 4 is a graph showing resistance of a fourth contact (M4C) chain;

FIG. 5 is a graph showing a change in resistance in a specific period;

FIG. 6 is a view showing a change in CD (Critical Dimension) in accordance with replacement of an ESC chuck;

FIG. 7 is a TEM photograph of a via hole;

FIG. 8 is a graph showing results in accordance with a via process and equipment splits;

FIG. 9 is a wafer map showing a ring type failure by FMAX;

FIG. 10 is a graph showing a relation between FMAX and a threshold voltage;

FIG. 11 is a view showing a threshold voltage window of a 1.5V standard transistor;

FIG. 12 is a view showing threshold voltage distributions in conditions of a second skew lot;

FIG. 13 is a wafer map having no ring type failure in a fast condition;

FIG. 14 is a margin map for a threshold voltage;

FIG. 15 is a view showing the yield improvement at a current threshold voltage; and

FIG. 16 is a view showing a yield distribution of an nMOS transistor changed into a fast condition.

### DETAILED DESCRIPTION

Hereinafter, a method of curing a failure in an analog device through a fast transistor having an optimized function area according to embodiments will be described in detail with reference to the accompanying drawings.

1. Proto Test Result of Analog Device

(1) Low yield and Ring Type Failure

Tests were performed with respect to skew and center lots in a CMOS device.

Each of the skew and center lots is split for an ion implantation condition and a CG CD (Critical Dimension). Both the center and the skew lots had a low yield. The skew lot was especially low, and showed near 0% yield in most groups, as shown in Table 1.

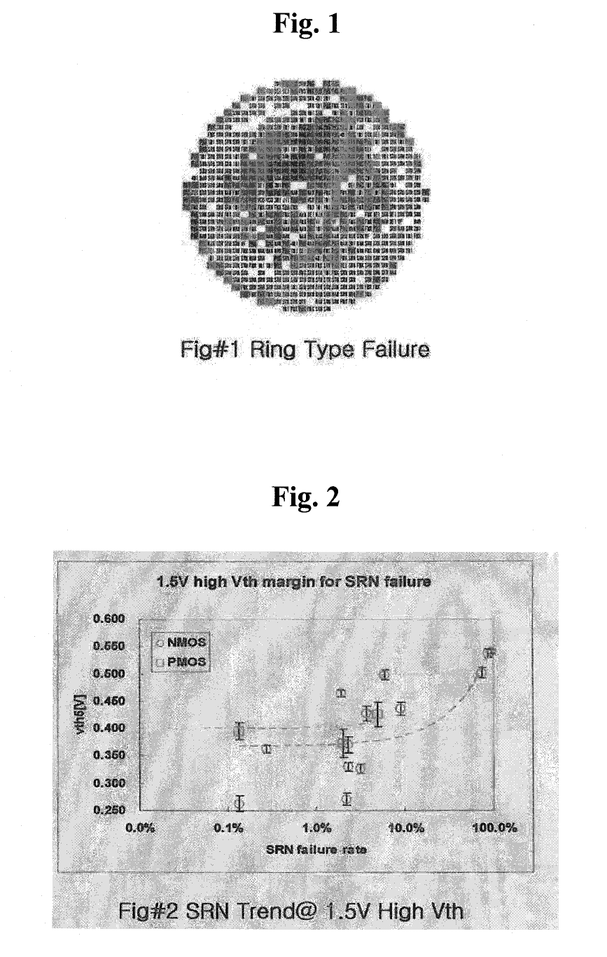

As shown in the wafer map of FIG. 1, a ring-shaped failure is observed at an edge of a wafer in the center lot.

TABLE 1

| | Condition (nMOS, pMOS, GC CD) | Average Yield (%) |
|---|---|---|
| Center Lot | CCC | 48 |
| Skew Lot | CCC | 29 |
| | CCH | 0 |
| | CCL | 53 |
| | LLC | 0 |
| | LLL | 0 |
| | HHC | 0 |
| | HHH | 0 |
| | HLC | 5 |
| | HLH | 0 |
| | HLL | 2 |
| | LHC | 0 |
| | LHH | 0 |
| | LHL | 0 |

F_{MAX} (Frequency MAX), IDD and SRN (SRAM Function) are the most renowned failure items.

For reference, “GC DC” means the length of a gate in Table

Table 2 shows a yield for each failure item in a skew lot group.

TABLE 2

| | CCL | CCH | CCL | LLC | LLL | HHC | HHH | HLC | HLH | HLL | LHC | LHH | LHL |
|---|---|---|---|---|---|---|---|---|---|---|---|---|---|
| FMX | 452 | 334 | 12 | 3 | 8 | 388 | 0 | 276 | 317 | 140 | 81 | 0 | 200 |
| IDD | 0 | 0 | 2 | 27 | 565 | 0 | 0 | 0 | 1 | 3 | 2 | 0 | 176 |
| SRN | 27 | 14 | 17 | 17 | 1 | 44 | 636 | 23 | 2 | 16 | 550 | 695 | 66 |
| Yield (%) | 29 | 0 | 53 | 0 | 0 | 0 | 0 | 5 | 0 | 2 | 0 | 0 | 0 |

(2) Analysis Result of Yield and PCM

In order to closely examine the reasons for a low yield, a relationship between the threshold voltages Vₜₕ and PCM items were analyzed. Here, “PCM” means electrical data.

In the skew lot, a relationship between the failure mode and the threshold voltage Vth were examined for each group.

As shown in FIG. 2, a relationship between an SRN (SRAM Function) and an nMOS 1.5V transistor has been found.

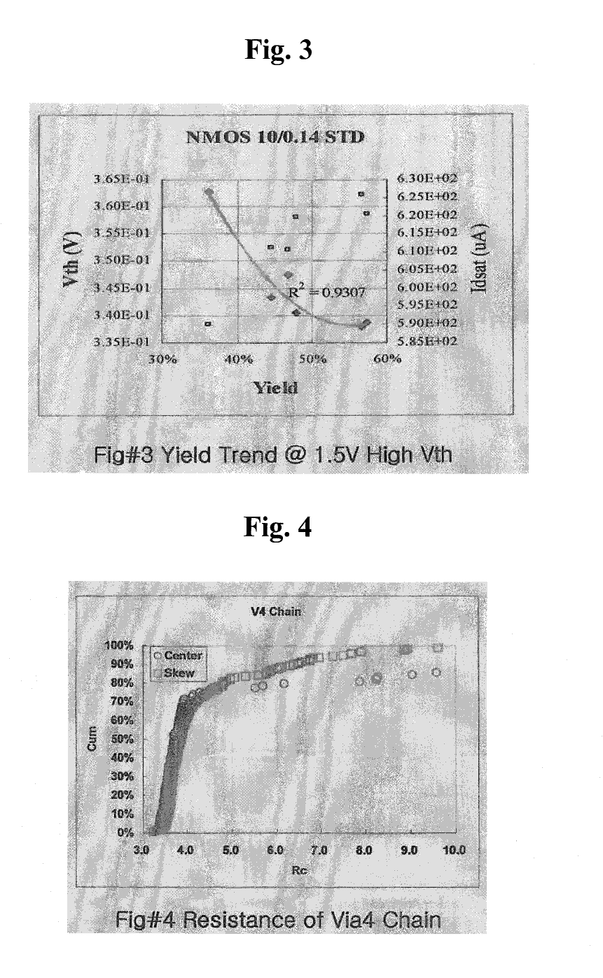

As shown in FIG. 3, if the nMOS 1.5V standard transistor moves to the fast side in the center lot, the yield is enhanced.

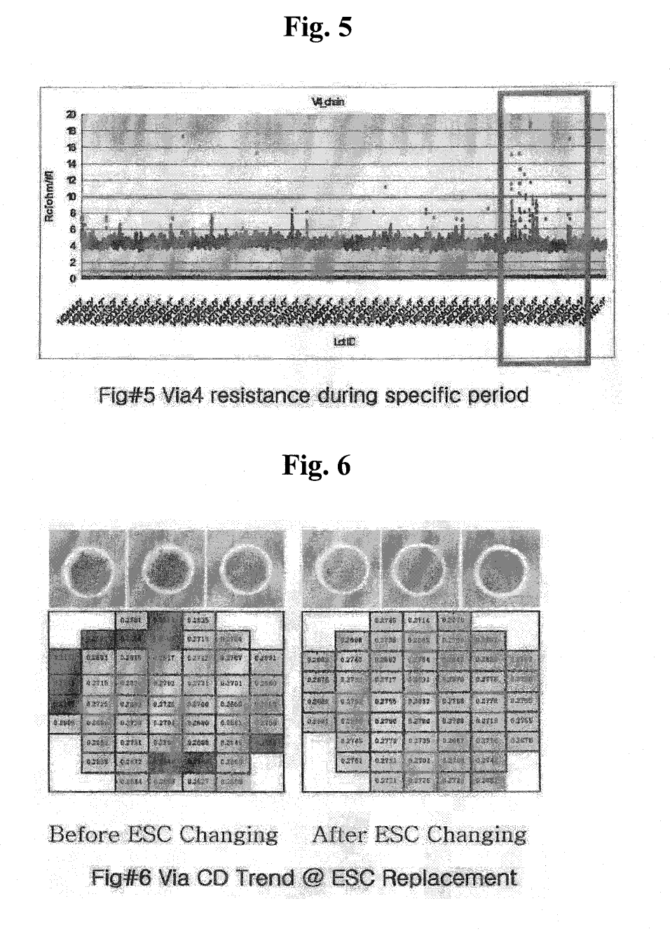

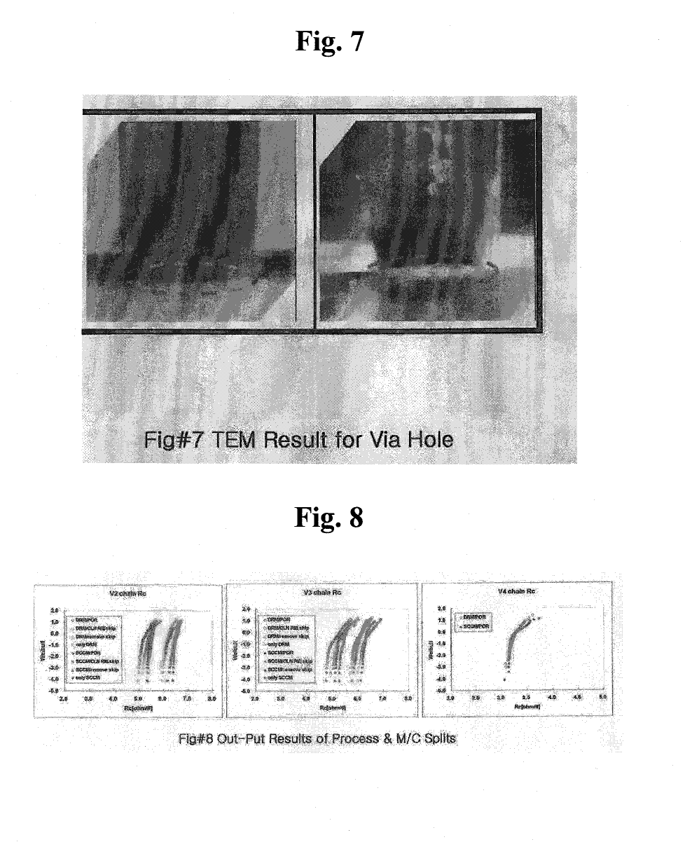

In the PCM items, the resistance Rc of a fourth contact (M4C) chain was anomalous, in that the resistance Rc of the M4C chain was high in some points. The skew and center lots also showed a similar trend. Since M4C processes for CMOS products are the same, the resistance Rc of an M4C chain in a T8F80 product, that is another product, was also checked. As a result, as shown in FIG. 5, the fluctuations in the M4C chain of the T8F80 product have been observed over a specific period.

The analyzed results have shown the relationship between the speed of nMOS and the yield to be just like the relationship between the yield and the threshold voltage Vth described above. The speed problem results from conditions in the nMOS transistor and Via resistance.

(3) Reason for Increase of M4C Resistance

It was estimated that the increase in the M4C resistance might be caused by chamber conditions. For example, the ESC chuck surface of the chamber was not clean because of polymer deposition. Investigating Via CDs (Critical Dimensions) before and after the replacement of ESC chucks, it can be seen that the Via CD before the replacement was smaller than that after the replacement as shown in FIG. 6. Moreover, the phenomenon in which the CD becomes small becomes more serious at the wafer edges, so that ring type failures occur.

Further, the result of a TEM scan at the position of the M4C failure showed that the Al surface of the M3C was exposed due to over etching in a via RIE process. The oxidation of the Al surface also increases via resistance. This is because the ESC chuck causes the temperature of a wafer to increase, and thus an etch rate is raised, which in turn causes the over etch.

2. Device Selection and Low Yield Improvement

(1) Via Process Evaluation

To solve the problem with the elevated via resistance, splits for the via process were implemented. Two main splits dealt with the pre-simplification of the M2C and M3C RIE steps and the post simplification of the POR. Here, POR means a process of record.

As shown in Table 3, such splits may also include equipment splits at M4C and M5C (DRM & SCCM). Here, TEL means Tokyo Electronics Co. Ltd., and DRM and SCCM are the model identifications of equipment produced by TEL.

TABLE 3

| Step | Condition |
|---|---|
| M2C RIE | TEL(DRM) |
| | TEL(SCCM) |
| M2C asher | Remove |
| | Skip |
| M2C CLN RIE | 70 sec |
| | Skip |
| M3C RIE | TEL(DRM) |
| | TEL(SCCM) |
| M3C asher | Remove |
| | Skip |
| M3C CLN RIE | 70 sec |
| | Skip |
| M4C RIE | TEL(DRM) |
| | TEL(SCCM) |
| M5C RIE | TEL(DRM) |
| | TEL(SCCM) |

The split results show differences in the via resistance in cases where the clean RIE step is skipped and where the clean RIE step is not skipped. There is no significant difference between the DRM and SCCM equipment splits. As shown in FIG. 8, there is no problem in resistance uniformly throughout the groups.

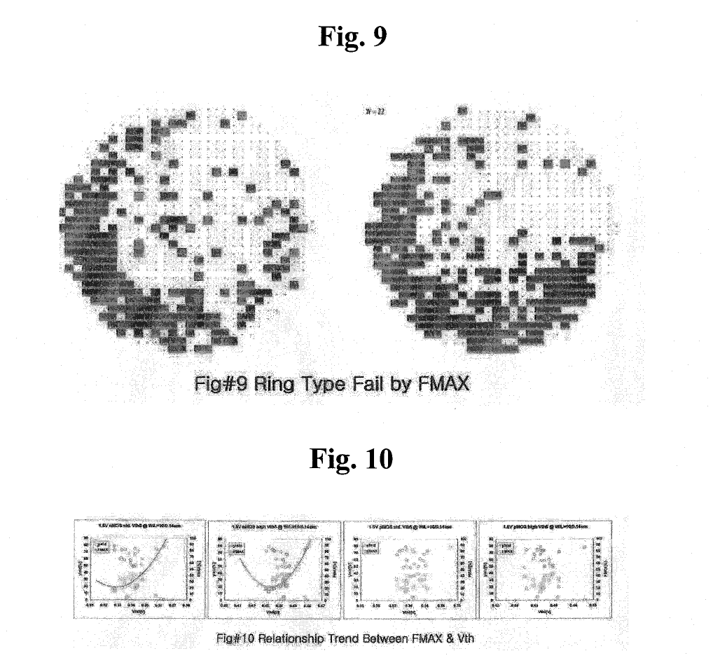

In the yield results shown in FIG. 9, the ring-shaped failure still appears under every condition, and FmAx is the most common failure. Therefore, it may be concluded that the major cause of the ring failure is not related to via resistance.

(2) Transistor Evaluation

FIG. 10 shows the relationship between PCM and yield versus the two major failure items—F_{MAX} and threshold voltage Vₜₕ. In pMOS, there is no relationship between F_{MAX} and Vₜₕ. However, in nMOS, there is a proportional relationship between the F_{MAX} failure rate and the threshold voltage Vₜₕ. Since the F_{MAX} failure rate increases rapidly with the increase of the Vₜₕ, the margin evaluation for a new device is required.

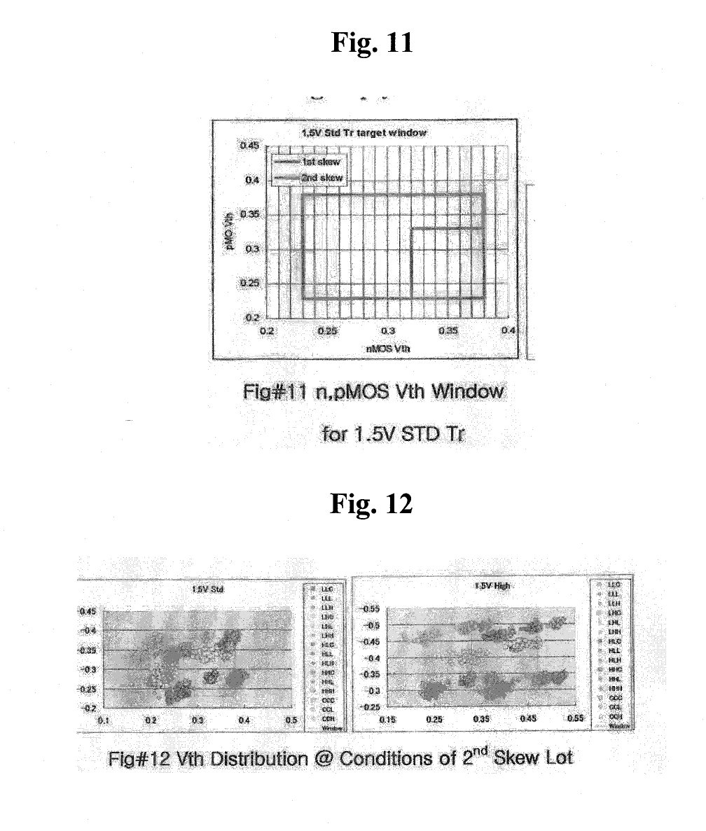

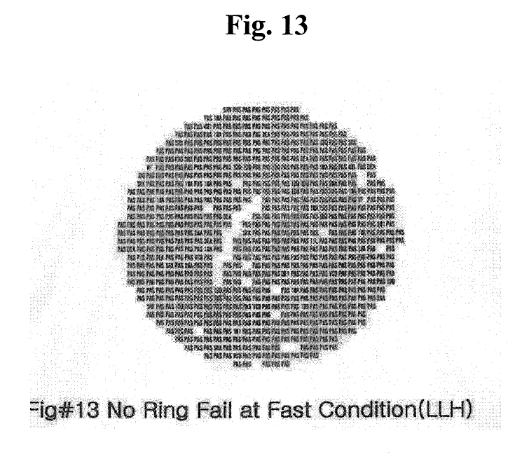

A second skew lot was used to evaluate the margin of the new device. As shown in FIG. 11, the difference in conditions between the first and second skew lots occurs when the threshold voltage window of the 1.5V standard transistor is changed in the second skew lot. Further, GC CD splits were performed in the same manner as described above. FIG. 12 and Table 4 show the threshold voltage distribution of the second skew lot and the yields of related groups, respectively.

TABLE 4

| | LLH | LLL | LHH | LHL | CCH | CCH | CCL | HLH | HLL | HHH | HHL |
|---|---|---|---|---|---|---|---|---|---|---|---|
| Wafer No. | 1 | 2 | 3 | 4 | 5 | 6 | 7 | 9 | 10 | 11 | 12 |
| Yield (%) | 88 | 0 | 0 | 0 | 1 | 0 | 60 | 1 | 5 | 0 | 0 |
| | CCC | CCC | CCC | LLC | LLC | LHC | LHC | HLC | HLC | HHC | HHC |
| Wafer No. | 13 | 15 | 17 | 18 | 19 | 20 | 21 | 22 | 23 | 24 | 25 |
| Yield (%) | 75 | 76 | 67 | 53 | 43 | 16 | 19 | 71 | 68 | 3 | 1 |

(3) Set-up for the Optimum Transistor

The thresold voltage Vₜₕ of a 1.5V high transistor was tuned using data of high yield groups in the second skew lot. A 1.5V standard condition and 2.5V and 3.3V basic conditions were unchanged. In the tuning conditions, a 1.5V high transistor was set to have a fast speed. Table 5 shows changes in ion implantation conditions.

TABLE 5

| | | 1st Mass | 2nd Mass |
|---|---|---|---|
| nMOS | Vth Target | 0.43 V | 0.36 V |
| | CNH | B + 5.6E12 | B + 3.1E12 |
| pMOS | Vth Target | 0.43 V | 0.37 V |
| | CPH | As + 6E12, P + 2.3E12 | As + 5.2E12 |

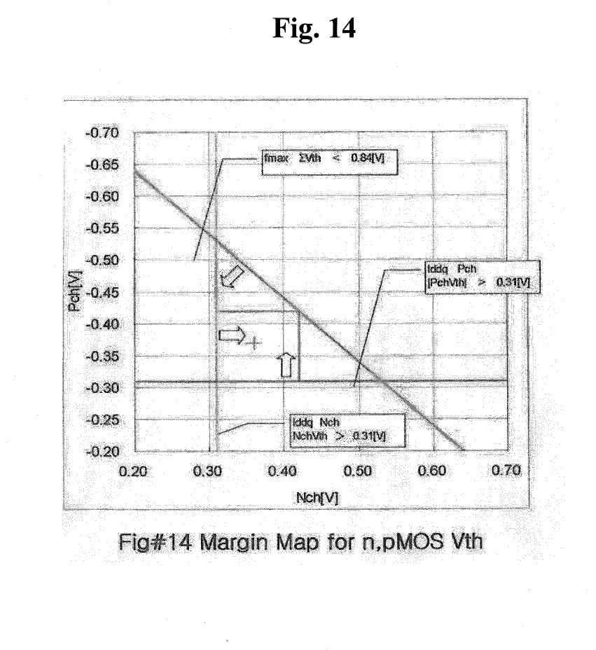

As shown in FIG. 14, a margin map was made on the basis of the yields of the first and second skew lots and PCM data for the purpose of tuning. The threshold voltage Vₜₕ was changed to prevent F_{MAX} failures from being produced.

In FIG. 14, the margin of the threshold voltage Vₜₕ according to the test transistors is about 100 mV. The margins of the threshold voltages Vₜₕin 1.5V high transistors, which are general CMOS products, are 150 to 200 mV. That is, the test transistors require a relatively tighter control in GC CD and gate oxide than other CMOS products. When the GC CD is changed by about 0.0 μm, the nMOS 1.5V High transistor is changed by 65 mV. This means that ±0.02 μm specification cannot be applied to a GC target unlike other CMOS devices. When considering the Vₜₕ margins of the test transistors, the control specification of GC CD is set as ±0.013 μM. The control specification is also applied to the thickness of the gate oxide. When the thickness of the gate oxide is changed by 1 Å in the 1.5V nMOS transistor, the threshold voltage Vₜₕthereof is changed by 30 mV. Accordingly, the thickness specification of the gate oxide is changed from 23±3 Å to 23±1 Å.

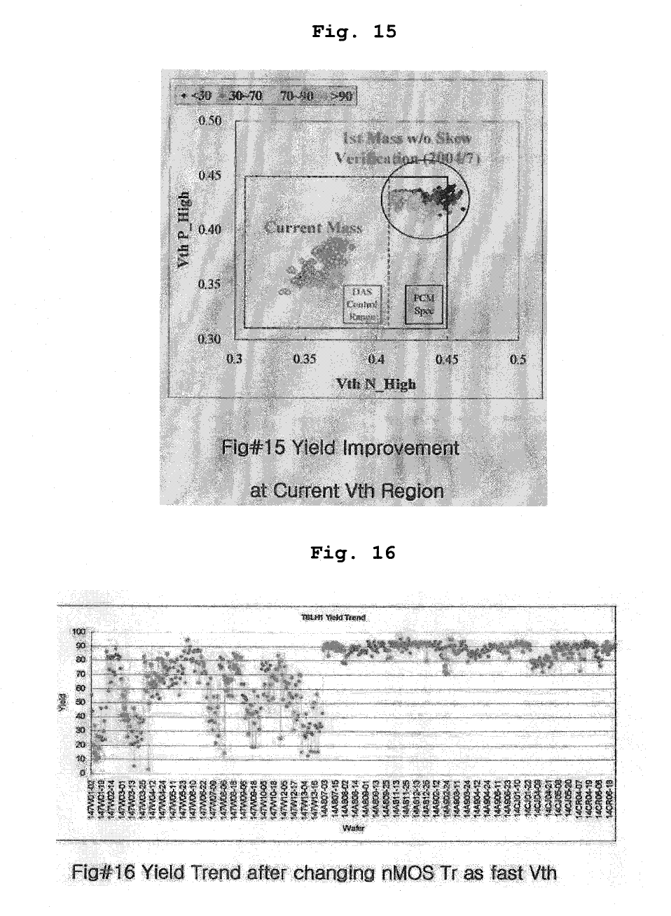

As described above, when the target of the 1.5V high transistor is modified to a fast condition, the ring-shaped failure phenomenon caused by F_{MAX} is eliminated, and thus a yield is improved as shown in FIG. 15. Moreover, an unstable and low yield has also been improved; a stable distribution is shown in FIG. 16. The first mass and the second skew lot are simultaneously implemented in a second skew center condition.

1. A method of curing a failure in an analog device, wherein a manufacturing margin of a threshold voltage is set as 100 mV, a control range of a gate CD (Critical dimension) is set as ±0.013 μm, and a thickness specification of a gate oxide is set as 23±1 Å, thereby eliminating a ring-shaped incidence of failures in a wafer chip map, the failures caused by F_{MAX} (Frequency MAX).

2. The method of claim 1, wherein a skew lot, in which the threshold voltage window of a 1.5V standard transistor is changed, is used to evaluate the margin of the threshold voltage.

3. The method of claim 1, wherein, when the thickness of the gate oxide is changed by 1 Å in a 1.5V nMOS transistor, the threshold voltage Vₜₕ thereof is changed by 30 mV.
